(19) United States
(12) Patent Application Publication
(10) Pub. No.: US 2024/0125215 A1
(43) Pub. Date: Apr. 18, 2024

(54) PARENT-CHILD PIC MODULE

(71) Applicant: GEODYNAMICS, INC., Millsap, TX (US)

(72) Inventors: Michael Wroblicky, Granbury, TX (US); Carson Brooks, Whitney, TX (US); Seth Powers, Weatherford, TX (US)

(73) Assignee: GEODYNAMICS, INC., Millsap, TX (US)

(21) Appl. No.: 18/047,560

(22) Filed: Oct. 18, 2022

(51) Int. Cl. E21B 43/1185; H05K 1/02; H05K 5/00

(52) U.S. Cl. CPC E21B 43/1185; H05K 1/0293; H05K 5/0052; H05K 5/0069; H01R 12/515

(57) ABSTRACT

A detonator module comprising: a housing with a first housing half and a second housing half, a detonator contained within the housing, a child board comprising a terminal header, wherein the child board is contained within the housing and the first housing half exposes the terminal header to an exterior of the housing, a switch mounted to an exterior surface of the housing, and a plurality of switch leads connecting the switch to the terminal header.

### TECHNICAL FIELD

The present disclosure relates, in general, to components of a perforating gun for use in an oil and gas well, and, in particular, the detonation technology employed in perforating guns.

### BACKGROUND OF THE INVENTION

In the oil and gas field, after a well is drilled to a desired depth H relative to the surface, and the casing protecting the wellbore has been installed and cemented in place, the wellbore is connected to the subterranean formation to extract the oil and/or gas. This process of connecting the wellbore to the subterranean formation may include a step of fluidly insulating with a plug a previously fractured stage of the well, a step of perforating a portion of the casing, which corresponds to a new stage, with a perforating gun such that various channels are formed to connect the subterranean formation to the inside of the casing, a step of removing the perforating gun, and a step of fracturing the various channels of the new stage by pumping a fluid into the channels. These steps are repeated until all the stages of the well are fractured.

The perforating guns are deployed into the well in groups, i.e., as a perforating gun string that includes a plurality of perforating guns. Each perforating gun may include any number of shaped charges. The shaped charges are the elements that are detonated inside the well for perforating the casing of the well. A switch is located within the perforating gun and signals the shaped charges to detonate. The switch is in electrical communication with the surface, so that the switch, and detonation, can be controlled from the surface. In recent years, perforating guns have become fully integrated, meaning that the detonation assembly is pre-installed in the perforating gun rather than being installed or wired in at the job site.

Often times the fully integrated gun is configured to work with a specific circuit board to properly function. Without the circuit board there is no method to incorporate the switch, without making the gun system longer and/or more difficult to load and handle. Additionally, using a different switch, such as a flying lead switch, will require changing components of the perforating gun assembly. In some instances, changing the switch may require wiring in the detonator on location, which is more time consuming and more prone to errors.

Therefore, what is needed is a detonation assembly that addresses one or more of the foregoing issues.

### SUMMARY OF THE INVENTION

One or more embodiments of the invention describe a programmable initiation control (“PIC”) module that is compatible with a variety of switches, including addressable and flying lead switches, for use in a perforating gun.

In further embodiments, features from specific embodiments may be combined with features from other embodiments. For example, features from one embodiment may be combined with features from any of the other embodiments. In further embodiments, additional features may be added to the specific embodiments described herein.

### BRIEF DESCRIPTION OF THE DRAWINGS

The accompanying drawings, which are included to provide further understanding and are incorporated in and constitute a part of this specification, illustrate disclosed embodiments and together with the description serve to explain the principles of the disclosed embodiments. In the drawings:

FIG. 1 is an illustration of a cross-sectional view of the PIC module, in accordance with embodiments of the present disclosure;

FIG. 2 is a perspective view of the PIC module, in accordance with embodiments of the present disclosure;

FIG. 3 is a perspective view of the PIC module, in accordance with embodiments of the present disclosure;

FIG. 4 is an illustration of a cross-sectional view of the PIC module with the mouse ear shunt, in accordance with embodiments of the present disclosure.

### DETAILED DESCRIPTION FO THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a perforating gun string. However, the embodiments discussed herein may be used for other tools that are used in a well.

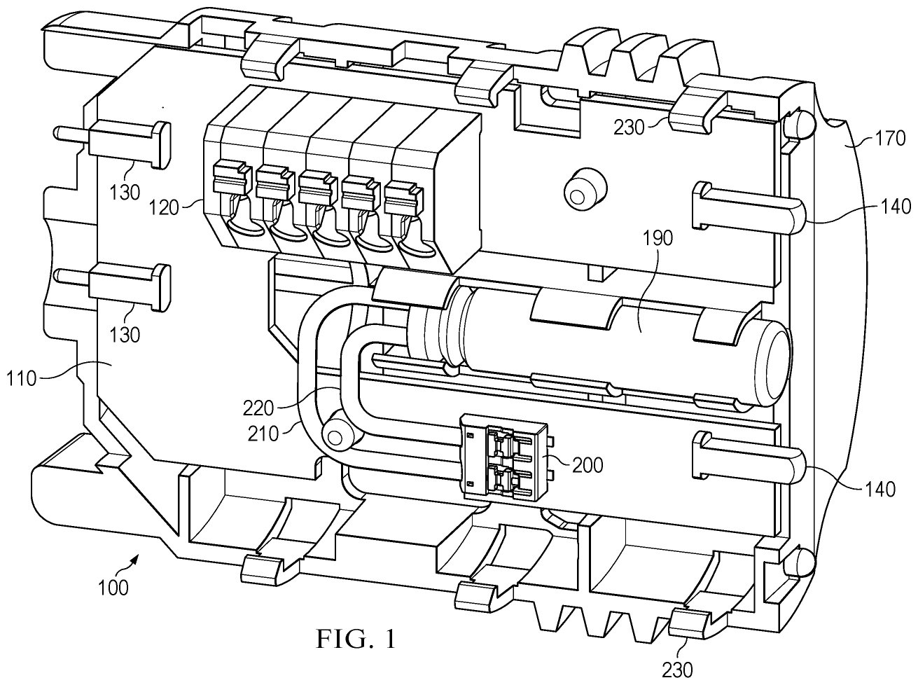

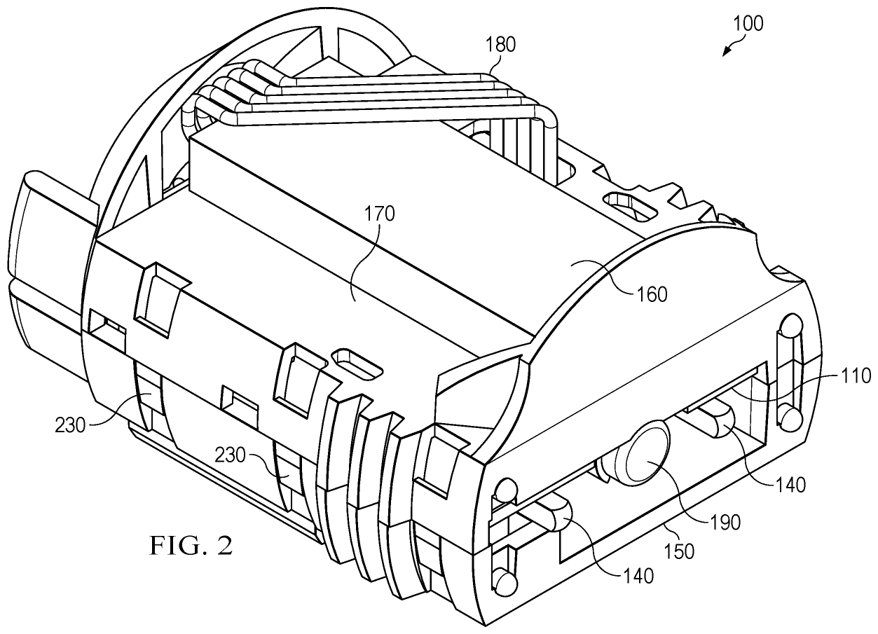

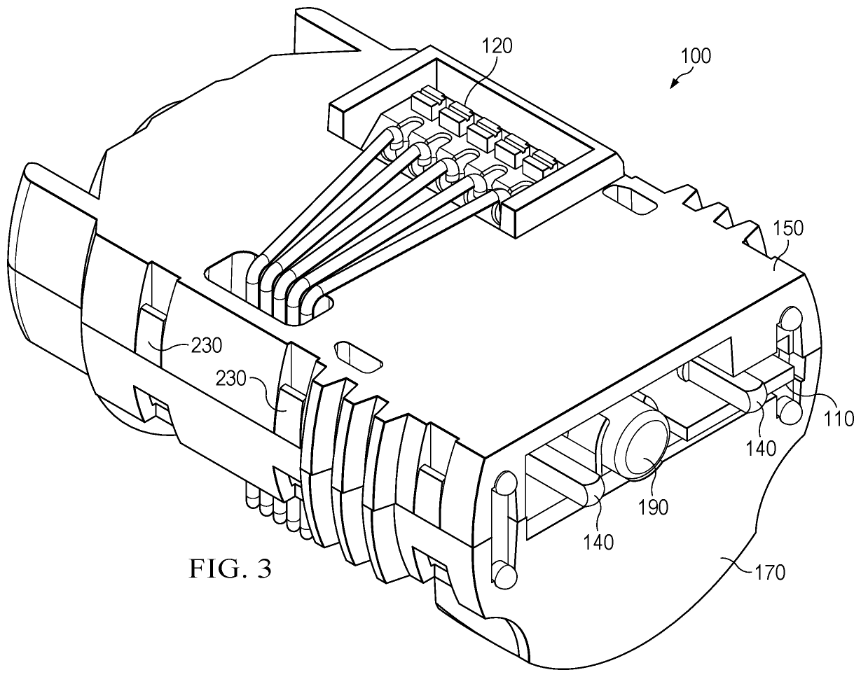

FIG. 1 illustrates a cross-sectional view of a PIC module 100. The PIC module 100 comprises a first clamshell half 150 and a second clamshell half 170 (FIGS. 2 and 3). In certain embodiments, the first clamshell half 150 and second clamshell half 170 are made out of injection molded plastic. In alternative embodiments, the first clamshell half 150 and second clamshell half 170 are made out of steel or aluminum. The second clamshell half 170 also includes tabs 230. The tabs 230 of the second clamshell half 170 are received by the first clamshell half 150 so that the second clamshell half 170 is connected to the first clamshell half 150 to form a housing. The housing has openings at the uphole end of the PIC module 100 and openings at the downhole end of the PIC module 100.

A child board 110 is contained within the housing formed by the first clamshell half 150 and the second clamshell half 170. The child board 110 is a printed circuit board connected to a switch 160. The child board 110 and switch 160 have a parent/child relationship. The switch 160 provides the foundation which the child board 110 can then implement. The child board 110 contains an uphole positive force contact 130 and a downhole rigid contact pin 140. The uphole positive force contact 130 and downhole rigid contact pins 140 enable the child board 110 to maintain an electrical connection within the perforating gun system. The uphole positive force contact 130 connects with the uphole contact within the perforating gun and the downhole rigid contact pin 140 connects with the downhole contact within the perforating gun. The openings in the PIC module 100 at the uphole end and the downhole end allow for access to the contacts 130 and pins 140. The PIC module 100 also contains a receiver 190 for the detonator. Advantageously, the receiver 190 is internally mounted within the PIC module 100 which provides additional protection for the detonator. Power wire 210 and ground wire 220 connect the detonator within the receiver 190 to a wire-to-board connection 200 that is connected to the child board 110. The child board 110 further contains a terminal header 120. In certain embodiments, the terminal header 120 is soldered to the child board 110. As discussed in more detail herein, the terminal header 120 provides a connection between the child board 110 and the switch 160. The wire-to-board connection 200 then allows the child board 110 and switch 160 to send signals to the detonator.

FIGS. 2 and 3 illustrate the outer view of the complete PIC module 100 with first clamshell half 150 connected to second clamshell half 170 via the tabs 230. FIG. 2 illustrates a first side view which illustrates the switch 160 positioned on the exterior of a second clamshell half 170.

FIG. 3 illustrates a second outer view of the PIC module. The exterior of the first clamshell half 150 allows access to the terminal header 120. In these embodiments, the switch 160 connects to the terminal header 120 via switch leads 180 which attach to the terminal header 120. The terminal header 120, discussed in more detail herein, enables the child board 110 to connect to the switch 160. The switch acts as a “parent” board that contains all the required components to digitally address the switch and pass appropriate commands through the perforating gun system or fire the attached detonator. It would be understood that a variety of switches could be used with this configuration. For example, in some embodiments, the switch 160 is a flying lead switch. In other embodiments, the switch 160 is an addressable switch.

In the illustrated embodiment, the terminal header is a no strip header that allows for stranded or solid core wiring. In the illustrated embodiment, the switch 160 is connected to the terminal header 120 via five switch leads 180. In the illustrated embodiment, the terminal header 120 is a screw terminal type. In other embodiments, the terminal header 120 can be spring loaded or crimped. In some embodiments, the terminal header 120 may exist on another child board that positions the terminal header 120 in a more preferred location. In some embodiments, the terminal header 120 is prewired to the inline child board 110.

In some embodiments, the switch 160 is retained with cable ties, rubber bands, wire ties, tape, or glue, among other methods of retention. In other embodiments, the flying lead switch may be housed in a pocket on the second clamshell half 170. The pocket allows for additional operational protection of the switch 160. The PIC module 100 discussed herein enables a user to replace the switch without replacing the entire module. This saves time and money.

In the configuration described above, the PIC module 100 exposes the terminal header 120 to the exterior components such as the switch. Exposing the terminal header 120 allows the PIC module 100 to ship with the current classification with the switch installed.

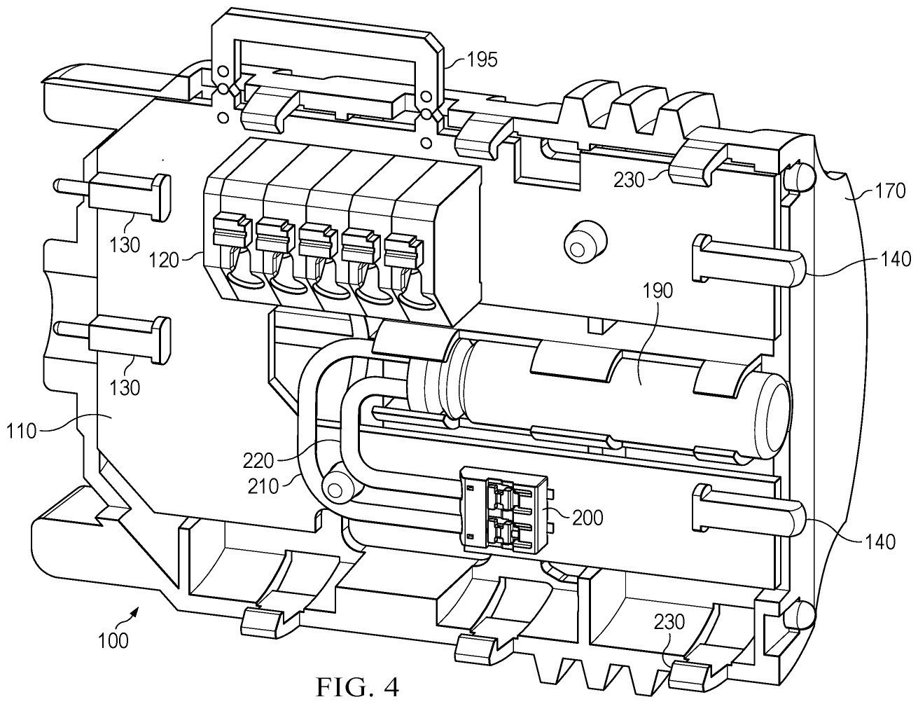

In some embodiments, the PIC module 100 is shipped without the switch installed. In these instances, the terminal header is shunted for detonator transport by a shunt large enough to require removal before switch installation. FIG. 4 illustrates the child board 110 with a mouse ear or break away shunt 195. The mouse ear shunt 195 enables the PIC module to be safely shipped without detonation. The mouse ear shunt 195 is a tab that shunts the electrical path used for the detonator. Once the PIC module 100 arrives on location, the mouse ear shunt 195 is removed. When the mouse ear shunt 195 is removed or broken off, it physically breaks the traces, which unshunts the detonator.

The PIC module disclosed in the embodiments discussed above is directly compatible with a PIC module currently used with certain existing commercial gun carriers, such as the STRATX system, offered by the applicant. Advantageously, the PIC module maintains an in-line circuit that allows for rotation about the carrier centerline axis. It would be understood that the uphole positive force contact 130, downhole rigid contact pins 140, and PIC module housing (the first clamshell half 170 and the second clamshell half 150) could be reconfigured so that it was compatible with a different perforating gun system.

It is understood that variations may be made in the foregoing without departing from the scope of the present disclosure. In several exemplary embodiments, the elements and teachings of the various illustrative exemplary embodiments may be combined in whole or in part in some or all of the illustrative exemplary embodiments. In addition, one or more of the elements and teachings of the various illustrative exemplary embodiments may be omitted, at least in part, and/or combined, at least in part, with one or more of the other elements and teachings of the various illustrative embodiments.

Any spatial references, such as, for example, “upper,” “lower,” “above,” “below,” “between,” “bottom,” “vertical,” “horizontal,” “angular,” “upwards,” “downwards,” “side-to-side,” “left-to-right,” “right-to-left,” “top-to-bottom,” “bottom-to-top,” “top,” “bottom,” “bottom-up,” “top-down,” etc., are for the purpose of illustration only and do not limit the specific orientation or location of the structure described above.

In several exemplary embodiments, while different steps, processes, and procedures are described as appearing as distinct acts, one or more of the steps, one or more of the processes, and/or one or more of the procedures may also be performed in different orders, simultaneously and/or sequentially. In several exemplary embodiments, the steps, processes, and/or procedures may be merged into one or more steps, processes and/or procedures.

In several exemplary embodiments, one or more of the operational steps in each embodiment may be omitted. Moreover, in some instances, some features of the present disclosure may be employed without a corresponding use of the other features. Moreover, one or more of the above-described embodiments and/or variations may be combined in whole or in part with any one or more of the other above-described embodiments and/or variations.

Although several exemplary embodiments have been described in detail above, the embodiments described are exemplary only and are not limiting, and those skilled in the art will readily appreciate that many other modifications, changes and/or substitutions are possible in the exemplary embodiments without materially departing from the novel teachings and advantages of the present disclosure. Accordingly, all such modifications, changes, and/or substitutions are intended to be included within the scope of this disclosure as defined in the following claims. In the claims, any means-plus-function clauses are intended to cover the structures described herein as performing the recited function and not only structural equivalents, but also equivalent structures. Moreover, it is the express intention of the applicant not to invoke 35 U.S.C. § 112, paragraph 6 for any limitations of any of the claims herein, except for those in which the claim expressly uses the word “means” together with an associated function. At least one specification heading is required. Please delete this heading section if it is not applicable to your application. For more information regarding the headings of the specification, please see MPEP 608.01(a).

1. A detonator module comprising:
a housing comprising:
a first housing half; and
a second housing half;
a detonator contained within the housing;
a child board comprising a terminal header, wherein the child board is contained within the housing and the first housing half exposes the terminal header to an exterior of the housing;
a switch mounted on an exterior surface of the second housing half; and
a plurality of switch leads connecting the switch to the terminal header.

2. The detonator module of claim 1, wherein the child board further comprises a pin connection at an uphole end to communicate with an uphole assembly and a pin connection at a downhole end to communicate with a downhole assembly.

3. The detonator module of claim 1, wherein the terminal header is a screw terminal type.

4. The detonator module of claim 1, wherein the switch is a flying lead addressable switch.

5. The detonator module of claim 1, wherein a mouse ear shunt is connected to the child board.
